(19) United States
(12) Patent Application Publication
(10) Pub. No.: US 2024/0177056 A1
(43) Pub. Date: May 30, 2024

(54) BATTERY CLASSIFIER PARTITIONING AND FUSION

(71) Applicant: GM Global Technology Operations LLC, Detroit, MI (US)

(72) Inventors: Yusheng Zou, Northville, MI (US); Ibrahim Haskara, Macomb, MI (US); Chengwu Duan, Shanghai (CN); Bharatkumar Hegde, Bloomfield Hills, MI (US)

(21) Appl. No.: 18/179,630

(22) Filed: Mar. 7, 2023

(30) Foreign Application Priority Data
Nov. 30, 2022 (CN) 202211516905.5

(51) Int. Cl. G06N 20/00

(52) U.S. Cl. CPC G06N 20/00

(57) ABSTRACT

A system and method for predicting a health of a battery. The system includes a sensor and a processor. The sensor is configured to obtain a battery data indicative of a parameter of the battery. A plurality of scores for the battery data is determined, and the battery data is partitioned into a plurality of subsets for which the scores have a different behavior for each of the subsets. The processor partitions the battery data into a plurality of subsets, determines a score for each of the plurality of subsets, wherein each score is related to the health of the battery, generates an overall score from the scores from each of the subsets, and predicts the health of the battery from the overall score.

### CROSS-REFERENCE TO RELATED APPLICATIONS

This application claims the benefit of Chinese Patent Application No. 202211516905.5 filed Nov. 30, 2022, the disclosure of which is incorporated herein by reference in its entirety.

### INTRODUCTION

The subject disclosure relates to testing battery packs used in electric vehicles and, in particular, to a system and method of testing a battery pack by partitioning data for testing and fusion of test results.

After a battery pack of a vehicle is manufactured, it is tested for quality. A healthy battery cell will naturally discharge at a discharge rate. Variations in the discharge rate and voltage of a battery cell are dependent on time, temperature, and other factors. The battery pack can be tested over days or weeks to determine whether a discharge rate of a battery cell is occurring at a normal or expected rate or at an abnormal or excessive rate. However, relying on a single test may be insufficient for detecting a faulty battery cell, due to the natural variations in various parameters of the battery cell. On the other hand, applying multiple tests can lead to conflicting results. Accordingly, it is desirable to provide a system and method for resolving differences in test results in order to determine faulty batteries and remove them from subsequent production stages of the vehicle.

### SUMMARY

In one exemplary embodiment, a method of predicting a health of a battery is disclosed. Battery data indicative of a parameter of the battery is obtained. The battery data is partitioned into a plurality of subsets. A score is determined for each of the plurality of subsets, wherein each score is related to the health of the battery. An overall score is generated from the scores from each of the subsets. The health of the battery is predicted from the overall score.

In addition to one or more of the features described herein, determining the score for a subset further includes inputting the subset into a machine learning model that generates the score. Determining the score for a subset further includes inputting the subset into a plurality of machine learning models to generate a plurality of scores and generating the overall score further includes generating a weighted sum of the scores that includes multiplying a score by a probabilistic coefficient associated with the machine learning model. The method further includes adjusting a probabilistic coefficient for the machine learning based on an evaluation metric associated with a machine learning model. The method further includes determining whether the plurality of subsets is at least one of non-overlapping and obtained using a same partitioning method. The method further includes fusing the scores to generate a plurality of subset scores and fusing the plurality of subset scores to generate the overall score. The method further includes partitioning the battery data into subsets based on a difference in a behavior of scores for the subsets.

In another exemplary embodiment, a system for predicting a health of a battery is disclosed. The system includes a sensor and a processor. The sensor is configured to obtain a battery data indicative of a parameter of the battery. The processor is configured to partition the battery data into a plurality of subsets, determine a score for each of the plurality of subsets, wherein each score is related to the health of the battery, generate an overall score from the scores from each of the subsets, and predict the health of the battery from the overall score.

In addition to one or more of the features described herein, the processor is further configured to determine the score for a subset further comprises inputting the subset into a machine learning model that generates the score. The processor is further configured to determine the score for a subset by inputting the subset into a plurality of machine learning models to generate a plurality of scores and generate the overall score by generating a weighted sum of the scores that includes multiplying a score by a probabilistic coefficient associated with the machine learning model. The processor is further configured to adjust the probabilistic coefficient for the machine learning based on an evaluation metric associated with a machine learning model. The processor is further configured to determine whether the plurality of subsets is at least one of non-overlapping and obtained using a same partitioning method. The processor is further configured to fuse the scores to generate a plurality of subset scores and fuse the plurality of subset scores to generate the overall score. The processor is further configured to partition the battery data into subsets based on a difference in a behavior of scores for the subsets.

In yet another exemplary embodiment, a method of predicting a health of a battery is disclosed. Battery data indicative of a parameter of the battery is obtained. A plurality of scores for the battery data is determined. The battery data is partitioned into a plurality of subsets, wherein the battery data is partitioned into subsets for which the scores have a different behavior for each of the subsets. A score is determined for each of the plurality of subsets, wherein each score is related to the health of the battery. An overall score is determined from the scores from each of the subsets. The health of the battery is predicted from the overall score.

In addition to one or more of the features described herein, determining the score for a subset further includes inputting the subset into a machine learning model that generates the score. Determining the score for a subset further includes inputting the subset into a plurality of machine learning models to generate a plurality of scores and generating the overall score further includes generating a weighted sum of the scores that includes multiplying a score by a probabilistic coefficient associated with the machine learning model. The method further includes adjusting a probabilistic coefficient for the machine learning based on an evaluation metric associated with a machine learning model. The method further includes determining whether the plurality of subsets is at least one of non-overlapping and obtained using a same partitioning method. The method further includes fusing the scores to generate a plurality of subset scores and fusing the plurality of subset scores to generate the overall score.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 shows a battery pack testing system in accordance with an exemplary embodiment;

FIG. 2 shows a flowchart of a method for determining a partitioning method for battery data;

FIG. 3 illustrates the effects of data partitioning in identifying a health of a battery;

FIG. 4 shows a flowchart illustrating a method for predicting a health of a battery using a plurality of machine learning models;

FIG. 5 shows a diagram illustrating details of the method of for predicting a health of a battery discussed in FIG. 4;

FIG. 6 shows a flowchart illustrating a method for fusing scores for a given subset of data;

FIG. 7 shows graphs for illustrating a process for fusing scores produced by the machine learning models disclosed herein;

FIG. 8 shows a flowchart illustrating a method for fusing subset scores to obtain an overall score and prediction; and

FIG. 9 shows a flowchart for determining weight values for the probability model of FIG. 6.

### DETAILED DESCRIPTION

The following description is merely exemplary in nature and is not intended to limit the present disclosure, its application or uses. It should be understood that throughout the drawings, corresponding reference numerals indicate like or corresponding parts and features.

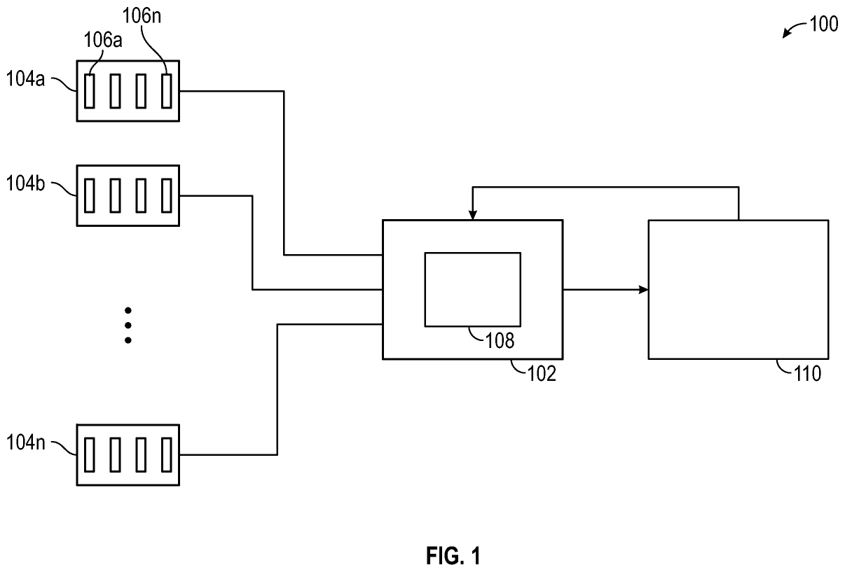

In accordance with an exemplary embodiment, FIG. 1 shows a battery pack testing system 100. The battery pack testing system 100 includes a machine 102 that receives data from one or more battery packs 104a-104n. Each battery pack 104a-104n includes a plurality of battery cells 106a-106n. Sensors at a given battery pack can take measurements of the battery pack and its battery cells, such as a voltage, discharge rate, temperature, etc. This data can be compiled across battery packs and provided to the machine 102. The machine 102 includes a controller 108 which performs calculation on the battery data to locate and determine which of the one or more battery packs 104a-104n are healthy and which are faulty, as well as which battery cells within a battery pack are faulty.

The controller 108 may include processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality. The controller 108 may include a non-transitory computer-readable medium that stores instructions which, when processed by one or more processors of the controller 108, implement a method of partitioning data and for fusing scores to accurately determine the health of a battery pack, according to one or more embodiments detailed herein.

The output from the machine 102/controller 108 can be shown at a display 110 to be viewed by an operator. The operator can view scores output by the controller 108 and select scores to identify faulty battery packs. The output from the machine 102 can also be used to adjust various models operating at the controller 108, such as altering a probabilistic weighting, determining an optimal method for partitioning data, etc.

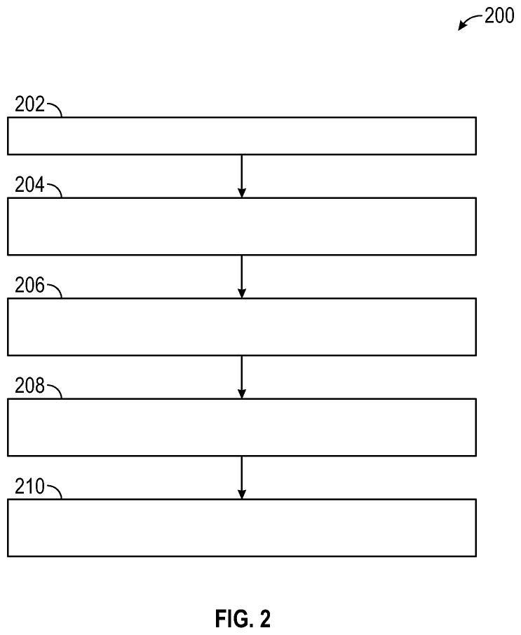

FIG. 2 shows a flowchart 200 of a method for determining a partitioning method for battery data. The battery data can be data for one or more battery packs, one or more battery modules, one or more battery cells, or a combination thereof. In box 202, the battery data is collected, measured, or obtained. The battery data can include data from one or more battery packs and/or form a plurality of cells within a battery pack. The battery data can include parameters such as a measurement time, a measured voltage, and measured voltage behavior (such as a discharge rate), an initial battery voltage, a temperature, a manufacturer of the battery or battery model, etc. In box 204, a classifier (i.e., a machine learning model) is applied to the battery data to generate classifier output. The classifier output can be a plurality of scores indicating a health of a battery cell or battery pack. The scores can be compared to a threshold to determine a plurality of predictions of the health of the battery (i.e., healthy or faulty). In box 206, a partition point is located within the data based on the scores. A partition point is a point or criterion that can be used to separate the battery data into two or more subsets. The partition point is selected such that a behavior of the scores is different between subsets. For example, battery data can be separated into time periods such that scores in one time period are increasing over time while scores in another time period are decreasing over time. The battery data can be partitioned based on various criteria, such as voltage range, time, initial voltages, discharge rate, etc. In alternate embodiments, the data can be grouped into subsets using two or more of these criteria (e.g., time period and temperature range).

In box 208, once the partition points are identified, they are used to partition the battery data into a plurality of subsets. In box 210, the plurality of subsets is input to one or more machine learning models to obtain individual scores that can be used to predict a health of the battery packs or battery cells.

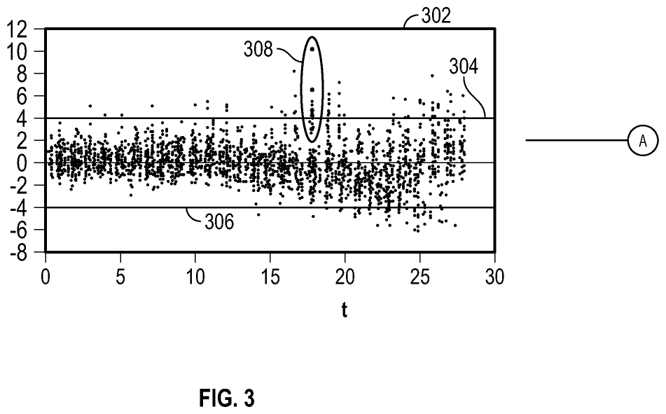

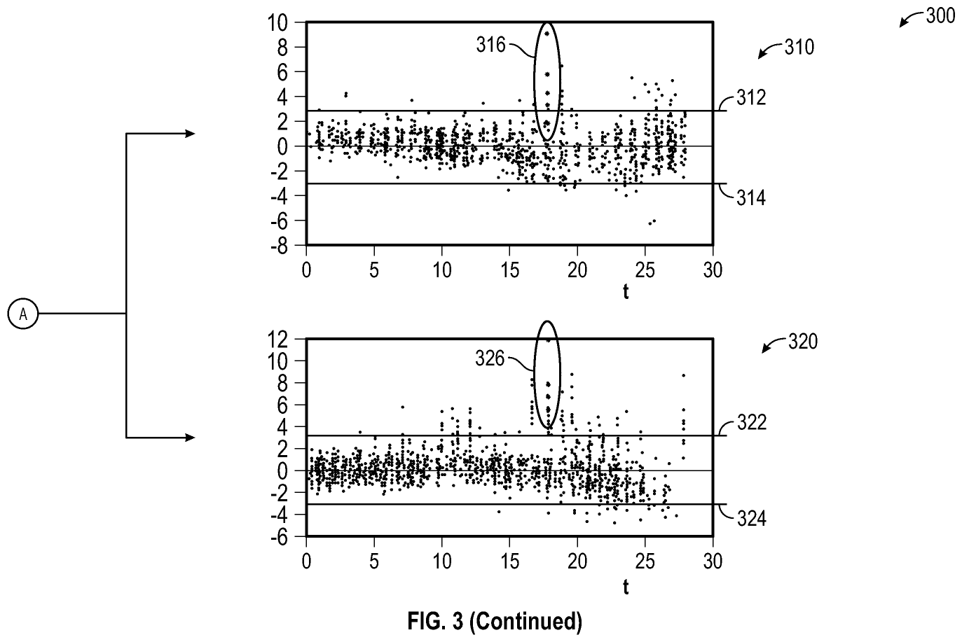

FIG. 3 illustrates an example of the effects of data partitioning in identifying a health of a battery. First graph 302 shows original battery data obtained over a period of time. Time is shown in days along the abscissa. Score value is shown along the ordinate axis. Scores are obtained during a soaking period which follows a manufacturing stage. Scores are shown for a plurality of battery cells and/or for a plurality of battery packs. A score in the first graph 302 is obtained during an application of the classifier and indicates a difference between the classifier output and a real or ground truth result. For example, a battery pack's overall discharge level resembles a period of 18 days, and the ground truth is that the battery pack has been soaking for 20 days. A point for the battery pack thus appears at (18, −2) of the first graph 302.

The dataset shown in first graph 302 includes data obtained at temperatures within a given temperature range, such as between about 22º C and about 30° C. Upper boundary 304 and lower boundary 306 define a range of healthy battery values. A score lying between the upper boundary 304 and the lower boundary 306 is considered to indicate a healthy battery pack, while a score lying outside of this range (i.e., either above the upper boundary 304 or below the lower boundary 306) is considered to indicate a faulty battery pack.

Each score in the first graph 302 has an associated identification number (not shown) that associates the score to a related battery pack or battery cell. Thus, a user or processor can determine which battery pack is healthy by locating its related score with respect to the upper boundary 304 and lower boundary 306. For example, a score can be determined to be faulty because it is above the upper boundary 304. The associated identification number of the score can be looked up and the associated battery pack can be identified as faulty.

Ellipse 308 includes scores for battery packs that are known to be faulty. The ellipse 308 includes five scores, four of which lie above the upper boundary 304 and thus can be correctly identified as faulty. However, one of the scores lies between the upper boundary 304 and the lower boundary 306 and thus is a false negative (i.e., identified as healthy even though it is faulty).

Second graph 310 and third graph 320 show score subsets resulting from partitioning the battery data based on temperature. The second graph 310 includes scores from a subset of the original battery data that are obtained at temperatures above 26° C. and the third graph 320 includes scores from a subset of the original battery data that are obtained at temperatures below 26° C. In the second graph 310, upper boundary 312 and lower boundary 314 cover a smaller range (i.e., [−3, 3]) than the boundaries of the first graph (i.e., [−4, 4]). However, the scores (now shown in ellipse 316) still include a false negative score. In third graph 320, upper boundary 322 and lower boundary 324 cover a smaller range (i.e., [−3, 3]) than the boundaries of the first graph (i.e., [−4, 4]). The scores (now shown in ellipse 326) are in alignment with the ground truth reality (i.e., the faulty battery cells have scores that indicated that the battery cells are faulty). The battery pack data that is associated with the scores in ellipse 326 belong to the partition that includes temperatures below 26° C.

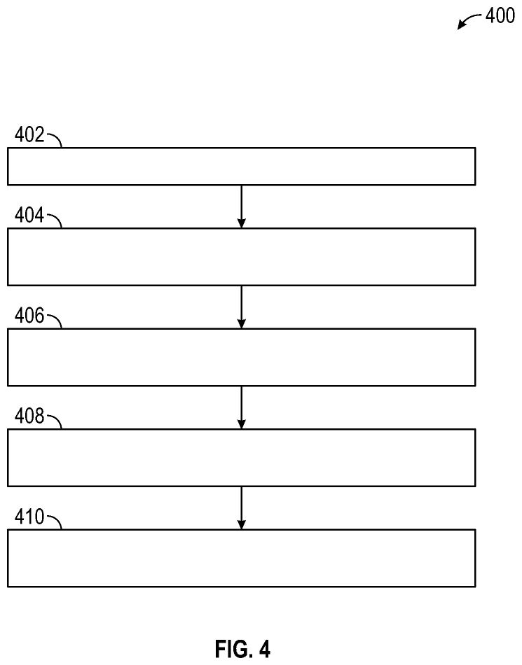

FIG. 4 shows a flowchart 400 illustrating a method for predicting a health of a battery using a plurality of machine learning models. In box 402, battery data is obtained or measured using sensors connected to the battery packs and/or battery cells. The battery data can be obtained during a testing period after manufacture of the battery pack and before installation of the battery pack in the vehicle. The testing period can be in the range of days or weeks. In box 404, the battery data is partitioned into a plurality of data subsets, using the portioning methods discussed with respect to FIG. 2.

In box 406, each data subset is entered into a plurality of machine learning models. Each machine learning model produces a score for the subset. In addition, a subset can be input into a model that is not a machine learning model. An exemplary machine learning model is a support vector machine (SVM) model that considers an interrelationship between cell groups and provides a confidence level or confidence score. Another model is a support vector regression (SVR) model that considers time into its calculations. In various embodiments, the score output by a machine learning model is a real number the represents the health of the battery pack. In box 408, the confidence scores are compiled on the subset level. In other words, the scores from the machine learning model pertaining to a subset of data are cross checked with each other and passed through an algorithm or probability model to determine a subset score. In box 410, the subset scores are cross-checked against each other to produce an overall score and prediction for the health of the battery, such as “healthy” or “faulty”.

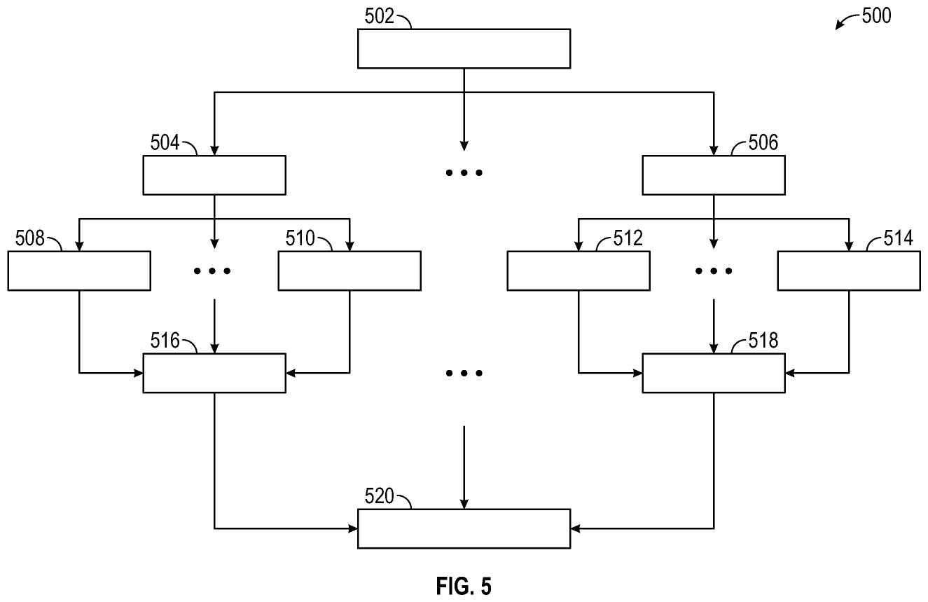

FIG. 5 shows a diagram 500 illustrating details of the method for predicting a health of a battery discussed in FIG. 4. For illustrative purposes, the battery data 502 is partitioned into k subsets (illustrated by subset 1 (504) through subset k (506)). Each subset is entered into a plurality of machine learning models. For example, subset 1 (504) is entered into models 1, . . . , n (illustrated by MLM1 (508) through MLMn (510). Subset k (506) is entered into models 1, . . . , m (illustrated by MLM1 (512) through MLMm (514)). In an embodiment, the same models are applied to each subset. In another embodiment, each subset can be entered into a different number of models. Also, the models applied to one subset need not be the same as the models applied to another subset.

The scores from each machine learning model are aggregated by subset and used to generate the subset score. For example, the scores output by MLM1 (508) through MLMn (510) as applied to the first subset 504 are fused to obtain subset score 1 (516). Also, the scores output by MLM1 (512) through MLMm (514) as applied to subset k (506) are fused to obtain subset score k (518). The subset scores are then fused to generate an overall score 520 which can be used to predict the health of the battery.

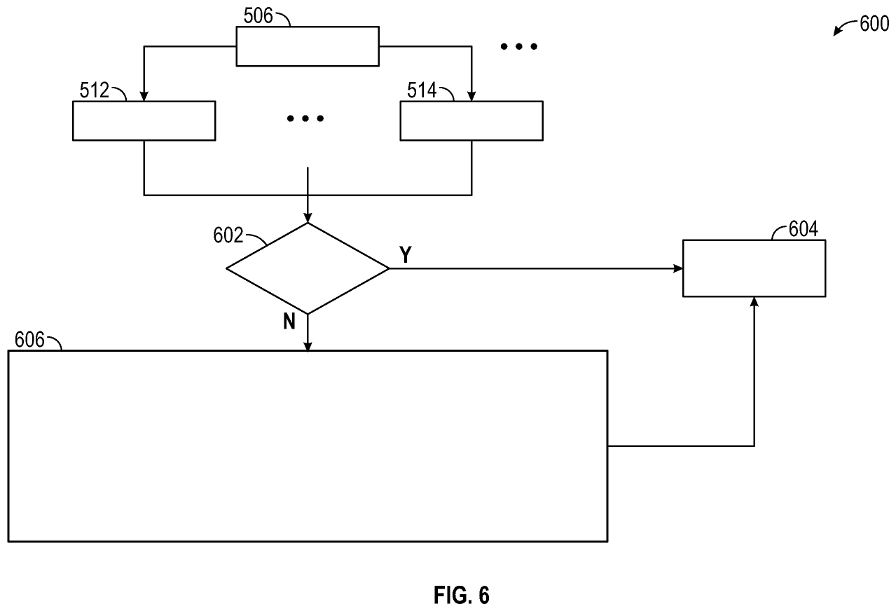

FIG. 6 shows a flowchart 600 illustrating a method for fusing scores for a given subset of data (such as the kth subset 506 in FIG. 5). The flowchart includes the subset k (506) and the machine learning models (MLM1 (512) and MLMm (514) shown in FIG. 5. In box 602, the scores are compared to each other to determine if they are in agreement. If the predictions from the machine learning models agree (i.e., all “healthy” or all “faulty”), the method proceeds to box 604, and the agreed-upon prediction becomes the prediction for the subset. If, at box 602, the predictions do not agree, the method proceeds to box 606.

In box 606, a probability model is applied to the scores to generate a subset score. If the score is an SVM score resulting from an SVM model, the score is normalized to a value in the domain [−1, 1]. If the score is an SVR score, the score is presented as a percentage error. The probability model assigns a probabilistic weight or probabilistic coefficient to each of the scores. The probabilistic weights are numbers in the range [0, 1] and which added up to 1. The weights can be adjusted based on an effectiveness of the model in obtaining a correct prediction. An overall score for the subset is obtained by adding up the weighted scores, as shown in Eq. (1):

S_{subset}=Σᵢ₌₁ⁿwᵢ·Sᵢ Eq. (1)

The method then proceeds from box 606 to box 604, in which the overall score for the subset is used to predict the health. If the S_{subset}>0, the battery is indicated as being healthy. If the S_{subset}<0, the battery is indicated as being faulty.

It is noted that, for each subset, the probabilistic weights assigned to the models can be different for each model. Using different probabilistic weights balances the performance and significance of each model within the overall score and leverages the capabilities of each model. For example, in some embodiments, in the beginning of a soaking period, the SVM score may be the most dominant in predicting the health of the battery pack. At later times in the soaking period, the time parameter becomes more important in predicting the health. Since time is explicitly expressed through the SVR score, the SVR score becomes more significant over SVM as time progresses.

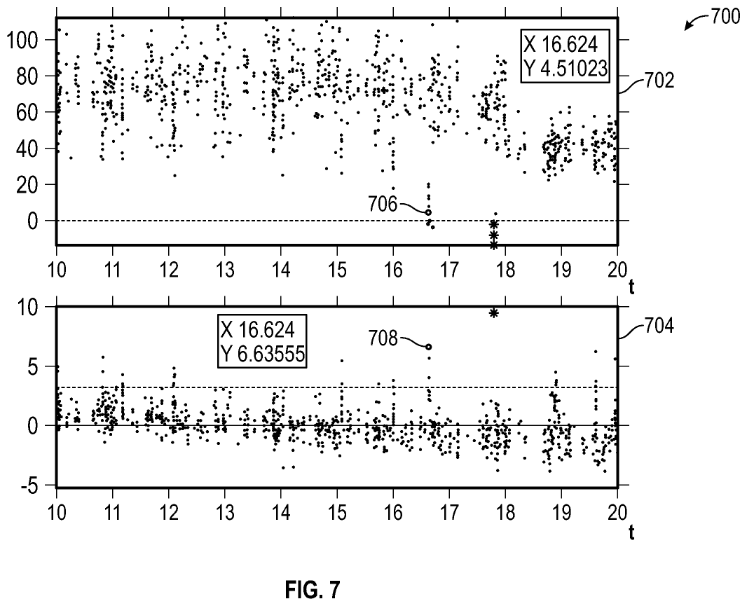

FIG. 7 shows graphs 700 for illustrating a process for fusing scores produced by the machine learning models disclosed herein. The top graph 702 shows SVM scores generated over a time period of about 10 days. The bottom graph 704 shows SVR scores generated over the same time period. In the top graph 702, for a battery pack with a time=16.624 days, the indicated SVM score 706 for a selected battery pack is about 4.51. The normalized SVM score is therefore equal to 0.04. In the bottom graph 704, for the same battery pack with time t=16.624 days, the SVR score 708 for the selected battery cell is about 6.64, which can be expressed as an error percentage of −120% (or −1.2) over the upper boundary (located at an SVR score of 3 on the ordinate axis).

For illustrative purposes, the SVM model has an associated a probabilistic weight w₁=0.8 and the SVR model has an associated probabilistic weight w₂=0.2. Thus, the overall score for the subset is 0.04*0.8+(−1.2)*0.2=−0.21. Since −0.21 is less than 0, the resulting prediction is that the battery cell is faulty.

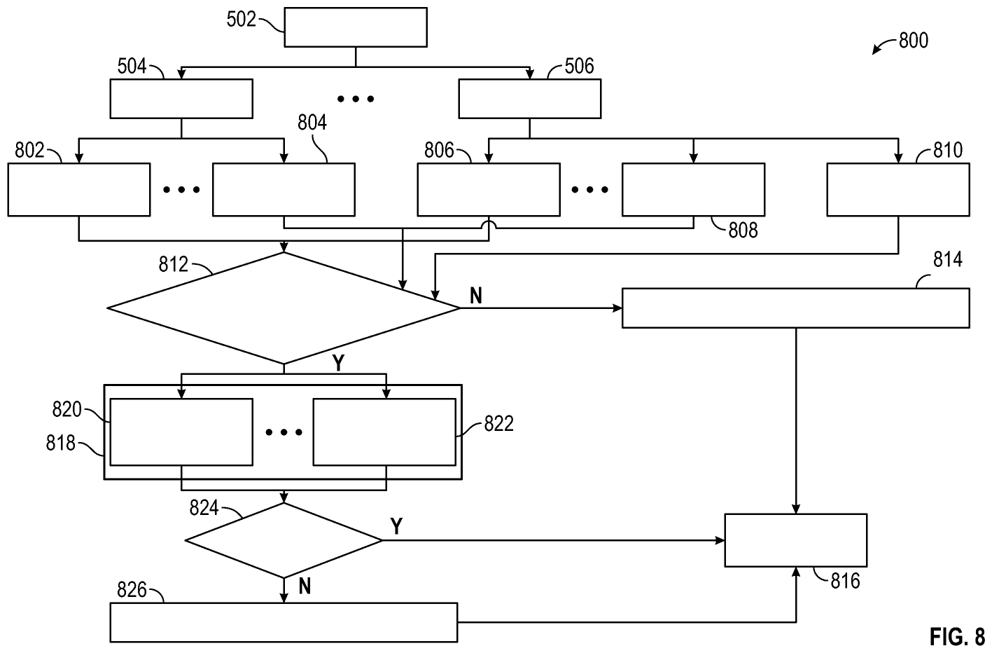

FIG. 8 shows a flowchart 800 illustrating a method for fusing subset scores to obtain an overall score and prediction. Battery data 502 is partitioned into a plurality of subsets, represented by subset 1 (504) through subset k (506). The subsets are entered into their respective models. For example, subset 1 (504) is entered into model 1 (802) through model n (804). Subset k (506) is entered into model 1 (806) through model n (808). Any of the subsets can also be entered to additional models, such as a logistic regression model 810.

In box 812, a decision is made concerning the relation between the subsets. If the subsets are obtained by using different partitioning methods or criteria and/or the subsets are overlapping, the method proceeds to box 814. In box 814, the scores are fused to obtain an overall score using the probability model discussed with respect to box 606 of FIG. 6. The overall score is the used at box 816 to provide a prediction on the health of the battery.

Returning to the decision of box 812, if the subsets are obtained using a same partitioning method or same partitioning criteria and the subsets do not overlap, the method proceeds to box 818. In box 818, the scores from each machine learning model are combined to form a combined score. For example, in box 820 all SMV scores are combined to form a single SVM score. In box 822, all scores obtained using a given model are combined to generate a single overall score for the given model.

In box 824, the combined scores obtained in box 818 are cross checked against each other to determine if there is agreement (i.e., all “healthy” or all “faulty”). If the combined scores are all in agreement, the method proceeds to box 816, in which the agreed-upon score is used to provide a prediction of the health of the battery pack. If, instead at box 824, the combined scores are not in agreement, the method proceeds to box 826. In box 826, the combined scores are fused to obtain an overall score using the probability model discussed with respect to box 606 of FIG. 6. In box 816, the overall score is used to provide a prediction for the health of the battery.

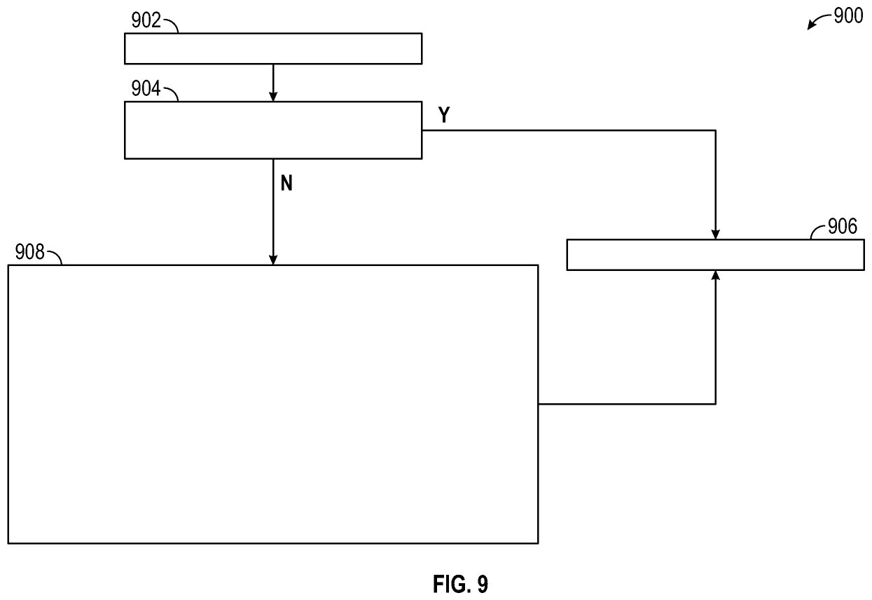

FIG. 9 shows a flowchart 900 for determining weight values for the probability model of FIG. 6. In box 902, the predictions or scores are obtained from each of the machine learning models. In box 904, the prediction or scores from the machine learning models are compared to predictions or scores form non-machine learning models, other models or ground truth results. If there is agreement between the scores/predictions, the method proceeds to box 906 in which the health of the battery is predicted. If the predictions/scores do not agree, the method proceeds to box 908.

In box 908, the weights of the probability model are assigned or adjusted based on an accuracy or precision evaluation metric which indicates the ability of the machine learning model to agree with reality. If the output of the machine learning model agrees with reality, the associated weight is increased. If the output disagrees, the associated weight is decreased. An initial value of the weight can be obtained from a correlation coefficient of machine learning model with ground truth data. The score calculations in box 908 are similar to the score calculations performed in box 606 of FIG. 6,

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A method of predicting a health of a battery, comprising:
obtaining a battery data indicative of a parameter of the battery;
partitioning the battery data into a plurality of subsets;
determining a score for each of the plurality of subsets, wherein each score is related to the health of the battery;
generating an overall score from the scores from each of the subsets; and
predicting the health of the battery from the overall score.

2. The method of claim 1, wherein determining the score for a subset further comprises inputting the subset into a machine learning model that generates the score.

3. The method of claim 2, wherein determining the score for a subset further comprises inputting the subset into a plurality of machine learning models to generate a plurality of scores and generating the overall score further comprises generating a weighted sum of the scores that includes multiplying a score by a probabilistic coefficient associated with the machine learning model.

4. The method of claim 3, further comprising adjusting a probabilistic coefficient for the machine learning based on an evaluation metric associated with a machine learning model.

5. The method of claim 1, further comprising determining whether the plurality of subsets is at least one of: (i) non-overlapping; and (ii) obtained using a same partitioning method.

6. The method of claim 1, further comprising fusing the scores to generate a plurality of subset scores and fusing the plurality of subset scores to generate the overall score.

7. The method of claim 1, further comprising partitioning the battery data into subsets based on a difference in a behavior of scores for the subsets.

8. A system for predicting a health of a battery, comprising:
a sensor configured to obtain a battery data indicative of a parameter of the battery; and
a processor configured to:
partition the battery data into a plurality of subsets;
determine a score for each of the plurality of subsets, wherein each score is related to the health of the battery;
generate an overall score from the scores from each of the subsets; and
predict the health of the battery from the overall score.

9. The system of claim 8, wherein the processor is further configured to determine the score for a subset further comprises inputting the subset into a machine learning model that generates the score.

10. The system of claim 9, wherein the processor is further configured to determine the score for a subset by inputting the subset into a plurality of machine learning models to generate a plurality of scores and generate the overall score by generating a weighted sum of the scores that includes multiplying a score by a probabilistic coefficient associated with the machine learning model.

11. The system of claim 10, wherein the processor is further configured to adjust the probabilistic coefficient for the machine learning based on an evaluation metric associated with a machine learning model.

12. The system of claim 8, wherein the processor is further configured to determine whether the plurality of subsets is at least one of: (i) non-overlapping; and (ii) obtained using a same partitioning method.

13. The system of claim 8, wherein the processor is further configured to fuse the scores to generate a plurality of subset scores and fuse the plurality of subset scores to generate the overall score.

14. The system of claim 8, wherein the processor is further configured to partition the battery data into subsets based on a difference in a behavior of scores for the subsets.

15. A method of predicting a health of a battery, comprising:
obtaining a battery data indicative of a parameter of the battery;
determining a plurality of scores for the battery data;
partitioning the battery data into a plurality of subsets, wherein the battery data is partitioned into subsets for which the scores have a different behavior for each of the subsets;
determining a score for each of the plurality of subsets, wherein each score is related to the health of the battery;
generating an overall score from the scores from each of the subsets; and
predicting the health of the battery from the overall score.

16. The method of claim 15, wherein determining the score for a subset further comprises inputting the subset into a machine learning model that generates the score.

17. The method of claim 16, wherein determining the score for a subset further comprises inputting the subset into a plurality of machine learning models to generate a plurality of scores and generating the overall score further comprises generating a weighted sum of the scores that includes multiplying a score by a probabilistic coefficient associated with the machine learning model.

18. The method of claim 17, further comprising adjusting a probabilistic coefficient for the machine learning based on an evaluation metric associated with a machine learning model.

19. The method of claim 15, further comprising determining whether the plurality of subsets is at least one of: (i) non-overlapping; and (ii) obtained using a same partitioning method.

20. The method of claim 15, further comprising fusing the scores to generate a plurality of subset scores and fusing the plurality of subset scores to generate the overall score.
